(19) United States
(12) Patent Application Publication
(10) Pub. No.: US 2026/0202478 A1
(43) Pub. Date: Jul. 16, 2026

(54) METHOD AND ELECTRONIC DEVICE WITH BATTERY STATE DETERMINATION

(71) Applicant: SAMSUNG ELECTRONICS CO., LTD., Suwon-si (KR)

(72) Inventors: Jinho KIM, Suwon-si (KR); Tae Won Song, Suwon-si (KR)

(73) Assignee: SAMSUNG ELECTRONICS CO., LTD., Suwon-si (KR)

(21) Appl. No.: 19/371,361

(22) Filed: Oct. 28, 2025

(30) Foreign Application Priority Data
Jan. 13, 2025 (KR) 10-2025-0005033

(51) Int. Cl. G01R 31/367; G01R 31/3842; G01R 31/392; H01M 10/42

(52) U.S. Cl. CPC G01R 31/367; G01R 31/3842; G01R 31/392; H01M 10/4285

(57) ABSTRACT

A processor-implemented method includes, based on first sensing data from a battery of an electronic device, determining a first value of a model parameter of a battery model, in response to the first value corresponding to a first threshold value, determining a first state of charge (SOC) of the battery using the battery model and the first sensing data, in response to a second value of the model parameter corresponding to a second threshold value set for the model parameter, determining a second SOC, determining a cumulative current value consumed in the battery between the first SOC and the second SOC, updating a value of a degradation parameter of the battery model based on the first SOC, the second SOC, and the cumulative current value, and determining the state of the battery using the battery model in which the value of the degradation parameter is updated.

### CROSS-REFERENCE TO RELATED APPLICATIONS

This application claims the benefit under 35 USC § 119 (a) of Korean Patent Application No. 10-2025-0005033, filed on Jan. 13, 2025 in the Korean Intellectual Property Office, the entire disclosure of which is incorporated herein by reference for all purposes.

### BACKGROUND

### 1. Field

The following description relates to a method and electronic device with battery state determination.

### 2. Description of Related Art

For battery management, states of batteries may be estimated using various methods. For example, the states of batteries may be estimated by cumulating currents of the batteries or by using a battery model (e.g., an electric circuit model).

The more often batteries are exposed to a management environment that accelerates degradation (e.g., fast degradation, fast discharging, or low-temperature or high-temperature environment), the higher the need for predicting state information of batteries reflecting degradation states of the batteries.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, a processor-implemented method includes, based on first sensing data measured from one or more sensors connected to a battery of an electronic device, determining a first value of a model parameter of a battery model configured to estimate a state of the battery, in response to the first value of the model parameter corresponding to a first threshold value, determining a first state of charge (SOC) of the battery using the battery model and the first sensing data, in response to a second value of the model parameter corresponding to a second threshold value set for the model parameter, determining a second SOC, determining a cumulative current value consumed in the battery during an interval between the first SOC and the second SOC, updating a value of a degradation parameter of the battery model based on the first SOC, the second SOC, and the cumulative current value, and determining the state of the battery using the battery model in which the value of the degradation parameter is updated.

The method may include determining a first model voltage of the battery using the battery model, determining a first model open circuit voltage (OCV) of the battery using the battery model, and determining a first model overpotential based on the first model voltage and the first model OCV, wherein the determining of the first SOC may include determining a first OCV of the battery based on a first sensing voltage of the battery among the first sensing data and the first model overpotential, and determining the first SOC corresponding to the first OCV.

The determining of the first SOC corresponding to the first OCV may include determining the first SOC corresponding to the first OCV using a look up table (LUT) that shows a relationship between an OCV and an SOC of the battery.

The determining of the second SOC may include obtaining second sensing data measured from the one or more sensors connected to the battery, determining a second value of the model parameter based on the second sensing data, determining whether the second value of the model parameter corresponds to a second threshold value set for the model parameter, in response to the second value of the model parameter corresponding to the second threshold value, determining a second model overpotential of the battery using the battery model, determining a second OCV of the battery based on a second sensing voltage of the battery among the second sensing data and the second model overpotential, and determining the second SOC corresponding to the second OCV.

The state of the battery may include a state of health (SOH) of the battery.

The model parameter may be an anode ion concentration.

The first threshold value set for the model parameter, which may be the anode ion concentration, may be a value between 0.85 and 0.65.

The second threshold value set for the model parameter, which may be the anode ion concentration, may be a value between 0.65 and 0.40.

The degradation parameter may be a change ratio of capacity of a cathode active material.

The first threshold value set for the model parameter, which may be the anode ion concentration, may be a value between 0.40 and 0.20.

The second threshold value set for the model parameter, which may be the anode ion concentration, may be a value between 0.20 and 0.05.

The degradation parameter may be an electrode balance shift.

The electronic device may be a mobile terminal.

In one or more general aspects, a non-transitory computer-readable storage medium may store code that, when executed by one or more processors, configures the one or more processors to perform any one, any combination, or all of operations and/or methods disclosed herein.

In one or more general aspects, an electronic device includes one or more processors configured to, based on first sensing data measured from one or more sensors connected to a battery of the electronic device, determine a first value of a model parameter of a battery model configured to estimate a state of the battery, in response to the first value of the model parameter corresponding to a first threshold value, determine a first state of charge (SOC) of the battery using the battery model and the first sensing data, in response to a second value of the model parameter corresponding to a second threshold value set for the model parameter, determine a second SOC, determine a cumulative current value consumed in the battery during an interval between the first SOC and the second SOC, update a value of a degradation parameter of the battery model based on the first SOC, the second SOC, and the cumulative current value, and determine the state of the battery using the battery model in which the value of the degradation parameter is updated.

In one or more general aspects, an electronic device includes one or more processors configured to obtain first sensing data measured from one or more sensors connected to a battery, determine a first value of a model parameter of a battery model configured to estimate a state of the battery based on the first sensing data, determine whether the first value of the model parameter corresponds to a first threshold value set for the model parameter, in response to the first value of the model parameter corresponding to the first threshold value, determine a first model overpotential of the battery using the battery model, determine a first open circuit voltage (OCV) of the battery based on a first sensing voltage of the battery among the first sensing data and the first model overpotential, determine a first state of charge (SOC) corresponding to the first OCV, determine a second OCV of the battery based on a second model overpotential of the battery determined in response to a second value of the model parameter corresponding to a second threshold value set for the model parameter, determine a second SOC corresponding to the second OCV, determine a cumulative current value consumed in the battery during an interval between the first SOC and the second SOC, update a value of a degradation parameter of the battery model based on the first SOC, the second SOC, and the cumulative current value, and determine the state of the battery using the battery model in which the value of the degradation parameter is updated.

The one or more processors may be configured to determine a first model voltage of the battery using the battery model, determine a first model OCV of the battery using the battery model, and for determining of the first model overpotential, determine the first model overpotential based on the first model voltage and the first model OCV.

The one or more processors may be configured to obtain second sensing data measured from the one or more sensors connected to the battery, determine the second value of the model parameter based on the second sensing data, determine whether the second value of the model parameter corresponds to the second threshold value set for the model parameter, in response to the second value of the model parameter corresponding to the second threshold value, determine a second model overpotential of the battery using the battery model, and for the determining of the second OCV of the battery, determine the second OCV of the battery based on a second sensing voltage of the battery among the second sensing data and the second model overpotential.

The model parameter may be an anode ion concentration.

The degradation parameter may be a change ratio of capacity of a cathode active material or an electrode balance shift.

Other features and aspects will be apparent from the following detailed description, the drawings, and the claims.

### BRIEF DESCRIPTION OF THE DRAWINGS

FIG. 1 illustrates an example of a configuration of a battery system.

FIG. 2 illustrates an example of a configuration of an electronic device.

FIG. 3 illustrates an example of an electrochemical model.

FIG. 4 illustrates an example of a cell voltage, a cathode open circuit potential (OCP), and an anode OCP according to battery discharging.

FIG. 5 illustrates an example of a method of determining a battery state.

FIG. 6 illustrates an example of a method of determining a model overpotential.

FIG. 7A illustrates an example of a method of determining a first OCV to determine a ratio of change in capacity of a cathode active material.

FIG. 7B illustrates an example of a method of determining a second OCV to determine a ratio of change in capacity of a cathode active material.

FIG. 8A illustrates an example of a method of determining a first OCV to determine an electrode balance shift.

FIG. 8B illustrates an example of a method of determining a second OCV to determine an electrode balance shift.

FIG. 9 illustrates an example of a method of determining a second OCV of a battery.

FIG. 10A illustrates an example of a fresh OCV curve shown in a state where a battery is fresh and an adjusted OCV curve determined based on states of charge (SOCs) determined during usage of the battery.

FIG. 10B illustrates an example of initial battery capacity determined based on a fresh OCV curve and current battery capacity determined based on an adjusted OCV curve.

FIG. 11 illustrates an example of a vehicle.

FIG. 12 illustrates an example of a mobile terminal.

FIG. 13 illustrates an example of an electronic device.

FIG. 14 illustrates an example of a method of determining a battery state.

FIG. 15 illustrates an example of an electronic device.

Throughout the drawings and the detailed description, unless otherwise described or provided, the same drawing reference numerals may be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” to specify the presence of stated features, numbers, operations, members, elements, and/or combinations thereof, other embodiments may exist where one or more of the stated features, numbers, operations, members, elements, and/or combinations thereof are not present.

Unless otherwise defined, all terms including technical and scientific terms used herein have the same meaning as commonly understood by one of ordinary skill in the art to which this disclosure pertains and after an understanding of the present disclosure. Terms, such as those defined in commonly used dictionaries, are to be interpreted as having a meaning that is consistent with their meaning in the context of the relevant art and the present disclosure, and the present disclosure, and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment,” and “one or more examples” has a same meaning as “in one or more embodiments”).

When describing the examples with reference to the accompanying drawings, like reference numerals refer to like components and a repeated description related thereto will be omitted. In the description of examples, detailed description of well-known related structures or functions will be omitted when it is deemed that such description will cause ambiguous interpretation of the present disclosure.

Although terms such as “first,” “second,” and “third,” or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but is used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on,” “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The same name may be used to describe an element included in the examples described above and an element having a common function. Unless otherwise mentioned, the descriptions on the examples may be applicable to the following examples and thus, duplicated descriptions will be omitted for conciseness.

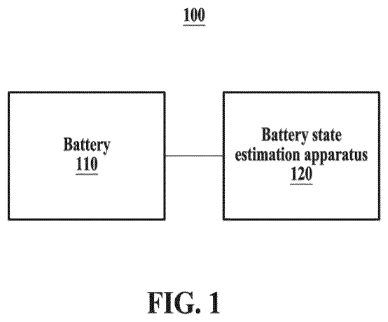

FIG. 1 illustrates an example of a configuration of a battery system.

Referring to FIG. 1, a battery system 100 includes a battery 110 and a battery state estimation apparatus 120.

The battery 110 may be one or more battery cells, battery modules, and/or battery packs, and may be a rechargeable battery.

The battery state estimation apparatus 120 may be an apparatus for estimating (or determining) a battery state for management of the battery 110 and include, for example, a battery management system (BMS). The battery state estimation apparatus 120 may collect sensing data by sensing the battery 110 using one or more sensors. For example, the sensing data may include voltage data, current data, and/or temperature data. According to an example, the battery state estimation apparatus 120 may not include a sensor and may receive sensing data from an independent sensor or another device. According to an example, the battery state estimation apparatus 120 may include the one or more sensors and the battery 110.

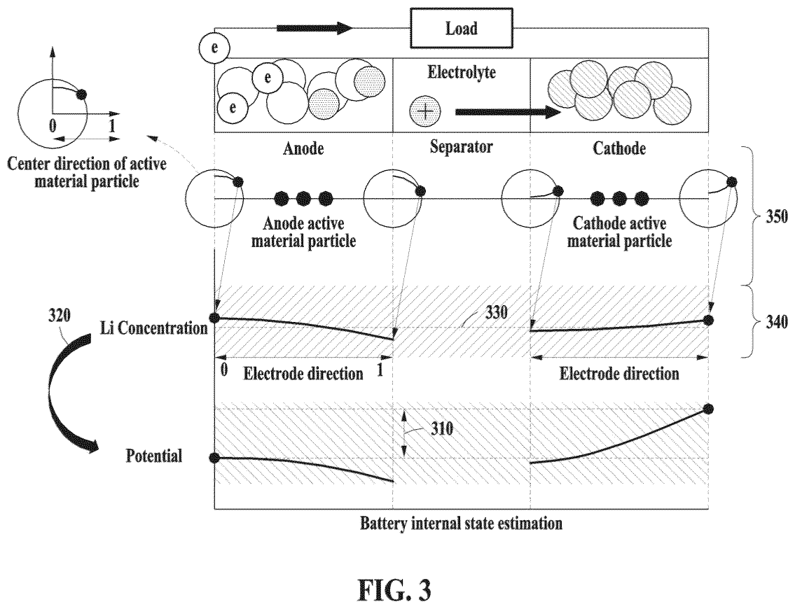

The battery state estimation apparatus 120 may estimate state information of the battery 110 based on the sensing data and output the result. The state information may include, for example, a state of charge (SOC), a relative state of charge (RSOC), a state of health (SOH), and/or abnormality state information. A battery model used to estimate the state information may be an electrochemical model, an example of which will be described with reference to FIG. 3.

The battery state estimation apparatus 120 may reflect a degradation state of the battery 110 in the battery model to estimate the state information reflecting the degradation state of the battery 110.

There may be various degradation factors of the battery 110, such as an increase in simple resistance component, a decrease in amount of cathode or anode active material, and/or an occurrence of lithium (Li) plating. In particular, the aspect of degradation may vary depending on a use pattern of a user who uses the battery, and a usage environment. For example, even when the battery 110 has the same reduction in the capacity due to degradation, the internal state of the degraded battery 110 may be different. In order to more accurately reflect the degradation of the battery to the battery model, degradation parameters of the battery estimated through an analysis of response characteristics (e.g., a voltage, etc.) of the degraded battery may be used to update the battery model.

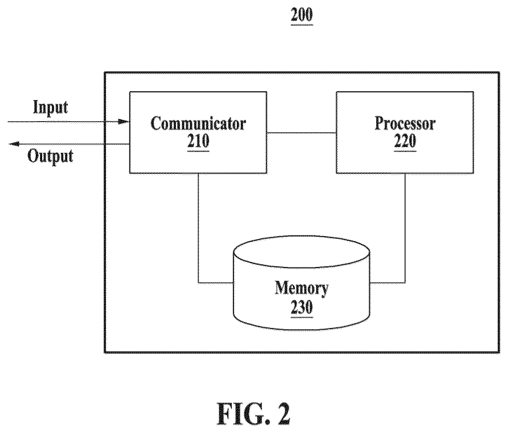

Examples of the battery state estimation apparatus 120 will be described in detail below with reference to FIGS. 2 to 13.

FIG. 2 illustrates an example of a configuration of an electronic device.

An electronic device 200 may include a communicator 210, a processor 220 (e.g., one or more processors), and a memory 230 (e.g., one or more memories). For example, the electronic device 200 may correspond to the battery state estimation apparatus 120 described above with reference to FIG. 1.

According to an example, the electronic device 200 may be, or be included in, a mobile terminal.

According to another example, the electronic device 200 may be, or be included in, a vehicle.

The communicator 210 may be connected to the processor 220 and the memory 230 and transmit and receive data to and from the processor 220 and the memory 230. The communicator 210 may be connected to another external device and transmit and receive data to and from the external device. Hereinafter, transmitting and receiving “A” may refer to transmitting and receiving “information or data indicating A.”

The communicator 210 may be implemented as circuitry in the electronic device 200. For example, the communicator 210 may include an internal bus and an external bus. In another example, the communicator 210 may be an element that connects the electronic device 200 to the external device. The communicator 210 may be an interface. The communicator 210 may receive data from the external device and transmit the data to the processor 220 and the memory 230.

The processor 220 may process the data received by the communicator 210 and data stored in the memory 230. A “processor” may be a hardware-implemented data processing device having a physically structured circuit to execute desired operations. The desired operations may include, for example, code or instructions included in a program. The hardware-implemented data processing device may include, for example, a microprocessor, a central processing unit (CPU), a processor core, a multi-core processor, a multiprocessor, an application-specific integrated circuit (ASIC), and a field-programmable gate array (FPGA).

The processor 220 may execute a computer-readable code (e.g., software) stored in a memory (e.g., the memory 230) and instructions triggered by the processor 220.

The memory 230 may store the data received by the communicator 210 and the data processed by the processor 220. For example, the memory 230 may store a program (or an application, or software). For example, the stored program may be a set of syntaxes that are coded and executable by the processor 220 to determine a state of a battery. For example, the memory 230 may be or include a non-transitory computer-readable storage medium storing code that, when executed by the processor 220, configures the processor 220 to perform any one, any combination, or all of operations and/or methods disclosed herein with reference to FIGS. 1-14.

The memory 230 may include at least one volatile memory, non-volatile memory, random-access memory (RAM), flash memory, a hard disk drive, and/or an optical disc drive.

The memory 230 may store an instruction set (e.g., software) for operating the electronic device 200. The instruction set for operating the electronic device 200 is executed by the processor 220.

The communicator 210, the processor 220, and the memory 230 will be described in detail below with reference to FIGS. 3 to 13.

FIG. 3 illustrates an example of an electrochemical model.

Referring to FIG. 3, an electrochemical model may estimate a state of charge of a battery by modeling internal physical phenomena of the battery, such as an ion concentration, a potential, and the like of the battery. For example, the electrochemical model may be represented by a physical conservation equation associated with an electrochemical reaction occurring on an electrode/electrolyte interface, an electrode/electrolyte concentration, and the conservation of electrical charges. For this, various model parameters such as a shape (e.g., a thickness, radius, etc.), an open circuit potential (OCP), and a physical property value (e.g. electrical conductance, ionic conductance, diffusion coefficient, etc.) may be used.

In the electrochemical model, various state variables, such as a concentration and a potential, may be coupled to one another. An estimated voltage 310 of the battery estimated by the electrochemical model may be a potential difference between both ends which are a cathode and an anode, and an ion concentration distribution of the cathode and the anode may affect the potential of the cathode and the anode (see 320). In addition, an average ion concentration of the cathode and the anode may be estimated as a SOC 330 of the battery.

The ion concentration distribution may be an ion concentration distribution 340 in an electrode or an ion concentration distribution 350 in an active material particle present at a predetermined position in the electrode. The ion concentration distribution 340 in the electrode may be a surface ion concentration distribution or an average ion concentration distribution of an active material particle positioned in an electrode direction, and the electrode direction may be a direction connecting one end of the electrode (e.g., a boundary adjacent to a collector) and the other end of the electrode (e.g., a boundary adjacent to a separator). In addition, the ion concentration distribution 350 in the active material particle may be an ion concentration distribution within the active material particle according to a center direction of the active material particle, and the center direction of the active material particle may be a direction connecting the center of the active material particle and the surface of the active material particle.

The measured voltage may be a voltage of a battery measured through a voltage measurer (or a sensor), and the estimated voltage 310 may be a voltage of the battery estimated by a battery model.

When an initial electrochemical model reflects a fresh state of the battery that is not degraded yet, an error between the estimated voltage 310 of the electrochemical model and the measured voltage of the actual battery that is degraded may gradually increase as the battery is degraded. In addition, even when the electrochemical model reflects an updated degradation parameter, an error between the estimated voltage 310 of the electrochemical model reflecting a previous degradation state and the measured voltage of the actual battery that is further degraded may gradually increase when the battery is continuously degraded according to a use pattern or environment.

The difference between the estimated voltage 310 and the measured voltage may gradually increase as the battery is degraded. Based on such a response characteristic difference between the estimated voltage 310 and the measured voltage, the battery state estimation apparatus of one or more embodiments may estimate a variation in the degradation parameter and reflect the variation in the electrochemical model. The degradation parameter may be a parameter indicating a degradation state of the battery, among a plurality of parameters included in the electrochemical model, and may include, for example, one of an anodic solid electrolyte interphase (SEI) resistance, a capacity for cathode active material, and an electrode balance shift, and/or a combination of two or more thereof.

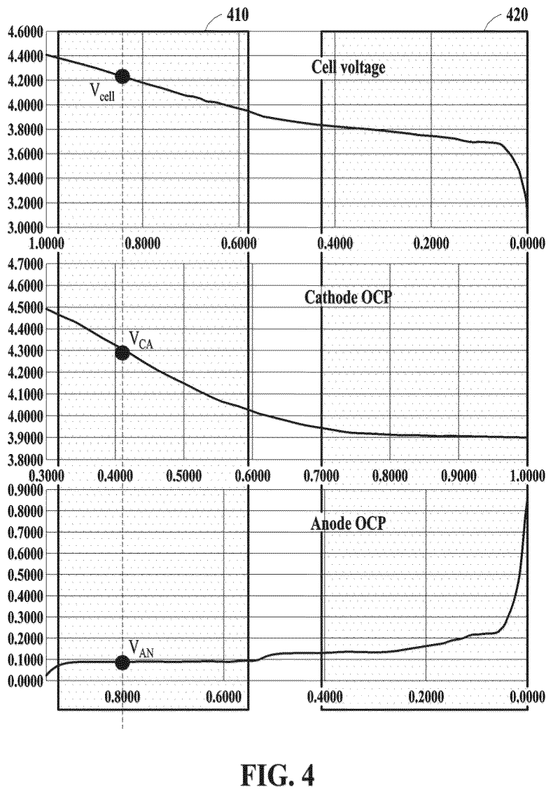

In order to estimate the state of the battery (e.g. the SOC and/or SOH) with higher accuracy by accurately updating the degradation parameters of the battery, the battery state estimation apparatus of one or more embodiments may accurately determine an open circuit voltage (OCV) of the battery. One or more examples of a method of determining a plurality of OCVs at a plurality of time points while the battery is being discharged and determining the state of the battery based on a plurality of SOCs determined based on the determined plurality of OCVs will be described in detail below with reference to FIGS. 4 to 10B.

FIG. 4 illustrates an example of a cell voltage, a cathode OCP, and an anode OCP according to battery discharging.

The cell voltage V_{cell} may be a measured voltage of the battery which may be determined to be a difference between a cathode OCP (e.g., V_{CA} or a cathode voltage) and an anode OCP (e.g., V_{AN} or an anode voltage) (e.g., V_{CA}-V_{AN}), and may gradually decrease as the battery is used and discharged. The cathode OCP may decrease relatively constantly, compared to the anode OCP, and a slope of decrease may become gradually gentle, whereas the anode OCP may have a relatively gentle slope, compared to the cathode OCP, in the early state, but have a steep slope last.

According to an example, the anode OCP may have a slope of “0” degrees or a slope close to “0” degrees in the early stage. In an example, that a slope is close to “0” degrees may mean the slope is less than or equal to a threshold value that is just above “0” degrees. A decrease in the capacity for cathode active material may be determined within an interval 410 in which the slope of the anode OCP is “0” degrees or close to “0” degrees. The interval 410 may correspond to an interval in which the SOC of the battery is large. For example, the interval 410 in which a decrease in the capacity for cathode active material is estimated may be an interval in which the state information (e.g., the SOC) of the battery is greater than a predetermined threshold or falls within a predetermined range. Further, since the state information of the battery has a certain correlation with the ion concentration and the capacity for active material of the battery, the interval 410 may be detected based on either one or both of the anode ion concentration and the capacity for active material of the battery in addition to the state information of the battery.

The capacity for cathode active material may be an indication that quantifies a phenomenon that an active material capable of accommodating lithium ions at the cathode decreases in response to aging. The more severe aging, the greater the decrease in the capacity for cathode active material.

According to an example, the cathode OCP may have a slope of “0” degrees or a slope close to “O” degrees in the late stage. An electrode balance shift may be determined within an interval 420 in which the slope of the cathode OCP is “0” degrees or close to “0” degrees. The interval 420 may correspond to an interval in which the SOC of the battery is small. For example, the interval 420 in which an electrode balance shift is estimated may be an interval in which the state information (e.g., the SOC) of the battery is greater than a predetermined threshold or falls within a predetermined range. Further, since the state information of the battery has a certain correlation with the ion concentration and the electrode balance shift of the battery, the interval 420 may be detected based on one of the anode ion concentration and the cathode ion concentration in addition to the state information of the battery.

A value of the degradation parameter may be updated in at least one of the intervals 410 and 420, and the degradation parameter may be used to update the battery model.

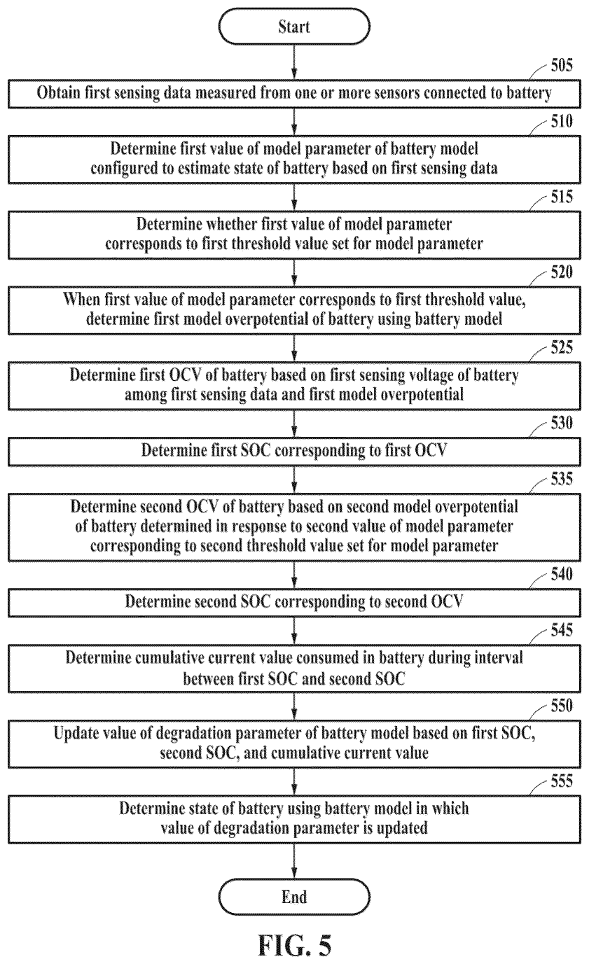

FIG. 5 illustrates an example of a method of determining a battery state.

Operations 505 to 555 of FIG. 5 may be performed by an electronic device (e.g., the battery state estimation apparatus 120 of FIG. 1 or the electronic device 200 of FIG. 2). For example, the electronic device may include at least one processor (e.g., the processor 220 of FIG. 2) and a memory (e.g., the memory 230 of FIG. 2). Operations 505 to 555 of FIG. 5 may be performed in the sequence and manner as illustrated in FIG. 5. However, one or more of the operations may be performed in a different order, one or more of the operations may be omitted, two or more of the operations may be performed in parallel or simultaneously, and/or other operations may be additionally performed without departing from the spirit and scope of the described embodiments.

In operation 505, the electronic device may obtain first sensing data measured from one or more sensors connected to a battery. For example, the first sensing data may include voltage data, current data, and/or temperature data.

In operation 510, the electronic device may determine a first value of a model parameter of a battery model configured to estimate a state of the battery based on the first sensing data. For example, the battery model may be an electrochemical model. For example, the model parameter may include an anode ion concentration, cathode ion concentration, anode OCP, cathode OCP, electrical conductance, ionic conductance, diffusion coefficient, anodic SEI resistance, capacity for the cathode active material, and/or electrode balance shift. The anodic SEI resistance, the capacity for the cathode active material, and the electrode balance shift may be model parameters and degradation parameters.

In operation 515, the electronic device may determine whether the first value of the model parameter corresponds to (e.g., has reached or is greater than or equal to) a first threshold value set for the model parameter. For example, the model parameter may be the anode ion concentration.

The first threshold value may correspond to a starting point of the interval 410 described above with reference to FIG. 4. The interval 410 may be an interval set to determine a ratio of change in the capacity for the cathode active material as a value of the degradation parameter. For example, when the model parameter is the anode ion concentration, the first threshold value set for the model parameter may be a value between 0.85 and 0.65.

The first threshold value may correspond to a starting point of the interval 420 described above with reference to FIG. 4. The interval 420 may be an interval set to determine the electrode balance shift as a value of the degradation parameter. For example, when the model parameter is the anode ion concentration, the first threshold value set for the model parameter may be a value between 0.40 and 0.20.

When the first value of the model parameter does not correspond to (e.g., has not reached) the first threshold value set for the model parameter, operations 505 to 515 may be performed repeatedly (e.g., repeatedly or iteratively performed until the first value of the model parameter corresponds to the first threshold value set for the model parameter).

In operation 520, when the first value of the model parameter corresponds to the first threshold value set for the model parameter, the electronic device may determine a first model overpotential of the battery using the battery model. For example, the model overpotential may be a value determined using a battery model. For example, the model overpotential may be determined based on an activation overpotential, an ohmic overpotential, and a concentration overpotential.

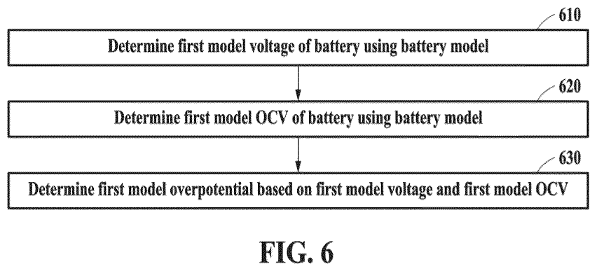

According to an example, the model overpotential may be a difference between a model OCV determined using the battery model and a model voltage, which is a voltage of the battery determined using the battery model. An example of a method of determining the first model overpotential will be described in detail below with reference to FIG. 6.

In operation 525, the electronic device may determine a first OCV of the battery based on a first sensing voltage of the battery among the first sensing data and the first model overpotential. For example, the sum of the first sensing voltage and the first model overpotential of the battery may be determined as the first OCV.

In operation 530, the electronic device may determine a first SOC corresponding to the first OCV. According to an example, the first SOC corresponding to the first OCV may be determined based on a predefined look up table (LUT) that shows a relationship between an OCV and an SOC of the battery. For example, when the state of the battery changes, the LUT may be redefined to correspond to the state of the battery. For example, as the values of one or more model parameters are updated, an OCV curve for the SOH or available battery capacity may change, and the LUT of the SOC may be redefined to correspond to the changed OCV curve.

In operation 535, the electronic device may determine a second OCV based on a second model overpotential of the battery determined in response to a second value of the model parameter corresponding to a second threshold value set for the model parameter. For example, the model parameter may be the anode ion concentration.

The second threshold value may correspond to an end point of the interval 410 described above with reference to FIG. 4. For example, when the model parameter is the anode ion concentration and the degradation parameter is a ratio of change in the capacity for the cathode active material, the second threshold value set for the model parameter may be a value between 0.65 and 0.40.

The second threshold value may correspond to an end point of the interval 420 described above with reference to FIG. 4. For example, when the model parameter is the anode ion concentration and the degradation parameter is an electrode balance shift, the second threshold value set for the model parameter may be a value between 0.20 and 0.05.

When the second value of the model parameter corresponds to the second threshold value set for the model parameter, the electronic device may determine a second model overpotential of the battery using the battery model.

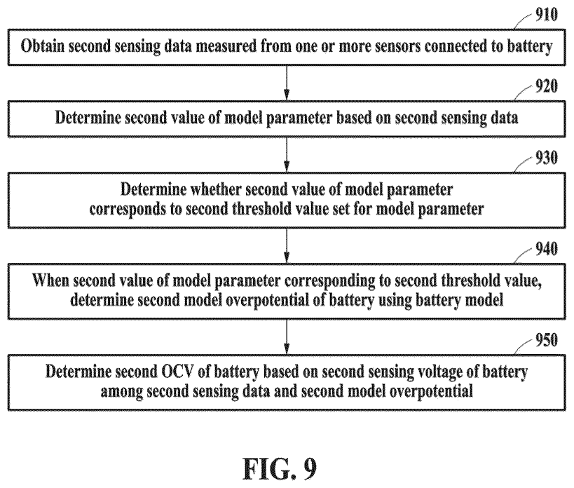

The electronic device may determine a second OCV of the battery based on a second sensing voltage of the battery among the second sensing data and the second model overpotential. The second sensing data may refer to sensing data that is measured at a different time point from the first sensing data among sensing data that is continuously or repeatedly measured. An example of a method of determining the second OCV will be described in detail below with reference to FIG. 9.

In operation 540, the electronic device may determine a second SOC corresponding to the second OCV. According to an example, the second SOC corresponding to the second OCV may be determined based on a predefined LUT for the relationship between the OCV and the SOC of the battery. The LUT used to determine the second SOC may be the same as the LUT used to determine the first SOC.

In operation 545, the electronic device may determine a cumulative current value consumed in the battery during the interval between the first SOC and the second SOC. For example, the cumulative current value may be the accumulated amount of charges for the interval between a first time point at which the first SOC is determined (or a time point at which the first sensing data is obtained) and a second time point at which the second SOC is determined (or a time point at which the second sensing data is obtained).

In operation 550, the electronic device may update the value of the degradation parameter of the battery model based on the first SOC, the second SOC, and the cumulative current value.

According to an example, the degradation parameter may be a ratio of change in the capacity of the cathode active material. The ratio of change in the capacity of the cathode active material may be determined for the interval 410 described above with reference to FIG. 4. For example, the electronic device may determine the current battery capacity available at a current time point (e.g., the second time point). The electronic device may determine the ratio of change in capacity based on current battery capacity and initial battery capacity. The ratio of change in the capacity of the cathode active material may be determined based on the determined ratio of change in battery capacity. For example, the ratio of change in battery capacity may be considered as a ratio of change in the capacity of the cathode active material.

The current battery capacity may be determined by Equation 1 below, for example.

$${Q}_{now} = \frac{{d}_{Q}}{{SOC}_{1} - {SOC}_{2}} \qquad Equation 1$$

In Equation 1, Q_{now} is the current battery capacity, do is the cumulative current value, SOC₁ is the first SOC, and SOC₂ is the second SOC.

The ratio of change in the battery capacity may be determined by Equation 2 below, for example.

$${Q}_{ratio} = \frac{{Q}_{now}}{{Q}_{init}} \qquad Equation 2$$

In Equation 2, Qᵣₐₜᵢₒ may be the ratio of change in the battery capacity, Q_{now} may be the current battery capacity, and Qᵢₙᵢₜ may be the initial battery capacity. The initial battery capacity may be the battery capacity when the battery is fresh.

The ratio of change in the battery capacity, Qᵣₐₜᵢₒ, may be determined by a ratio of change in the cathode capacity, CAᵣₐₜᵢₒ.

According to an example, the degradation parameter may be an electrode balance shift. The electrode balance shift may be determined for the interval 420 described above with reference to FIG. 4. The electrode balance shift may be determined based on the ratio of change in the battery capacity determined by Equations 1 and 2. For example, the electrode balance shift may be determined by Equation 3 below, for example.

$$EBshift = {Q}_{ratio} - 1 \qquad Equation 3$$

In Equation 3, EBshift may be the electrode balance shift, and Qᵣₐₜᵢₒ may be the ratio of change in the cathode capacity.

The electronic device may update the value of the degradation parameter by updating at least one of the ratio of change in the cathode active material or the determined electrode balance shift to be applied to the battery model.

In operation 555, the electronic device may determine the state of the battery using the battery model in which the value of the degradation parameter is updated. For example, the electronic device may adjust the OCV curve for the available battery capacity. The electronic device may generate a standard discharge overpotential curve based on the adjusted OCV curve. The electronic device may re-determine the current battery capacity of the battery based on the standard discharge overpotential curve. The electronic device may determine an SOH as the state of the battery by Equation 4 below, for example.

$$SOH = \frac{{Q}_{new}}{{Q}_{init}} \qquad Equation 4$$

In Equation 4, Q_{new} may be the re-determined current battery capacity, and Qᵢₙᵢₜ may be the initial battery capacity.

FIG. 6 illustrates an example of a method of determining a model overpotential.

According to an example, operations 610 to 630 of FIG. 6 may be related to operation 520 described above with reference to FIG. 5. For example, operation 520 may include operations 610 to 630.

Operations 610 to 630 may be performed by an electronic device (e.g., the battery state estimation apparatus 120 of FIG. 1 or the electronic device 200 of FIG. 2). For example, the electronic device may include at least one processor (e.g., the processor 220 of FIG. 2) and a memory (e.g., the memory 230 of FIG. 2). Operations 610 to 630 of FIG. 6 may be performed in the sequence and manner as illustrated in FIG. 6. However, one or more of the operations may be performed in a different order, one or more of the operations may be omitted, two or more of the operations may be performed in parallel or simultaneously, and/or other operations may be additionally performed without departing from the spirit and scope of the described embodiments.

In operation 610, the electronic device may determine a first model voltage of the battery using the battery model. The first model voltage may be a voltage of the battery estimated using the battery model.

In operation 620, the electronic device may determine a first model OCV of the battery using the battery model. The first model OCV may be an OCV of the battery estimated using the battery model.

In operation 630, the electronic device may determine the first model overpotential based on the first model voltage and the first model OCV. For example, a value obtained by subtracting the first model voltage from the first model OCV may be determined as the first model overpotential.

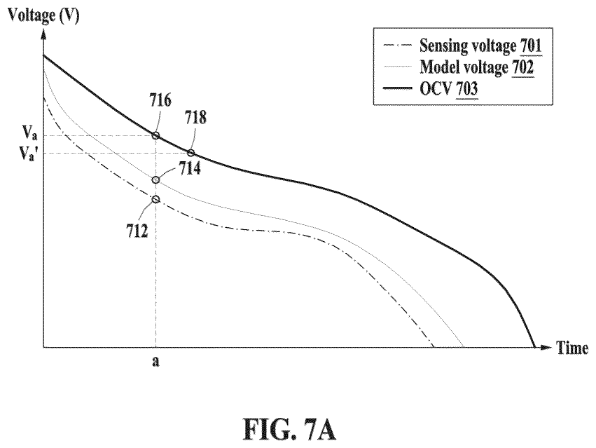

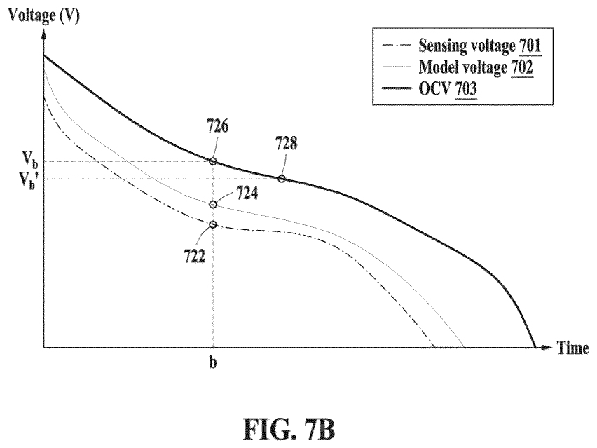

FIG. 7A illustrates an example of a method of determining a first OCV to determine a ratio of change in capacity of a cathode active material.

The x-axis of the graph shown may correspond to the time during which the battery is being discharged and/or the amount of SOC is decreasing.

According to an example, at a time point a, the first value of the model parameter may correspond to the first threshold value set for the model parameter. For example, a value of the anode ion concentration determined based on the sensing data may correspond to the first threshold value (e.g., 0.75) at the time point a. The time point a may be in the interval 410 described above with reference to FIG. 4. A first model voltage 714 of a model voltage graph 702 of the battery may be determined using the battery model. A first model OCV 716 of an OCV graph 703 of the battery may be determined using the battery model. The model overpotential may be determined by a value obtained by subtracting the first model voltage 714 from the first model OCV 716. A first OCV 718 of the OCV graph 703 may be determined as the sum of the model overpotential and a first sensing voltage 712 of a sensing voltage graph 701.

According to an example, a first SOC corresponding to the first OCV 718 may be determined. For example, the first SOC corresponding to the first OCV may be determined based on a predefined LUT for the relationship between an OCV curve 703 and an SOC of the battery.

FIG. 7B illustrates an example of a method of determining a second OCV to determine a ratio of change in capacity of a cathode active material.

The x-axis of the graph shown may correspond to the time during which the battery is being discharged or the amount of decrease in the SOC.

According to an example, at a time point b, the second value of the model parameter may correspond to the second threshold value set for the model parameter. For example, a value of the anode ion concentration determined based on the sensing data may correspond to the second threshold value (e.g., 0.5) at the time point b. The time point b may be in the interval 410 described above with reference to FIG. 4. A second model voltage 724 of the battery may be determined using the battery model. A second model OCV 726 of the battery may be determined using the battery model. The model overpotential may be determined by a value obtained by subtracting the second model voltage 724 from the second model OCV 726. A second OCV 728 may be determined as the sum of the model overpotential and a second sensing voltage 722.

According to an example, a second SOC corresponding to the second OCV 728 may be determined. For example, the second SOC corresponding to the second OCV may be determined based on the predefined LUT for the relationship between the OCV curve 703 and the SOC of the battery.

According to an example, the ratio of change in the capacity of the cathode active material may be determined as the value of the degradation parameter based on the cumulative current value consumed in the battery during the interval between the time point a and the time point b (or between the first SOC and the second SOC).

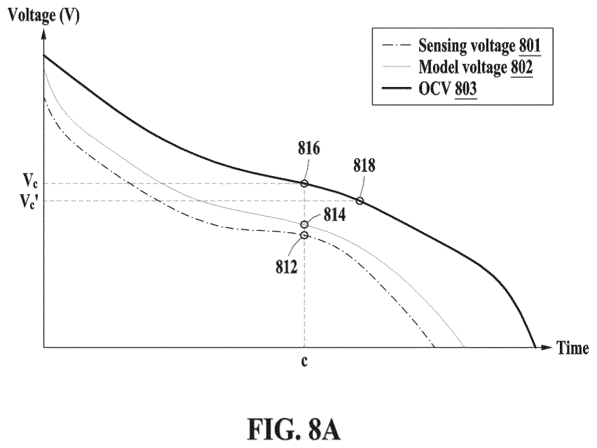

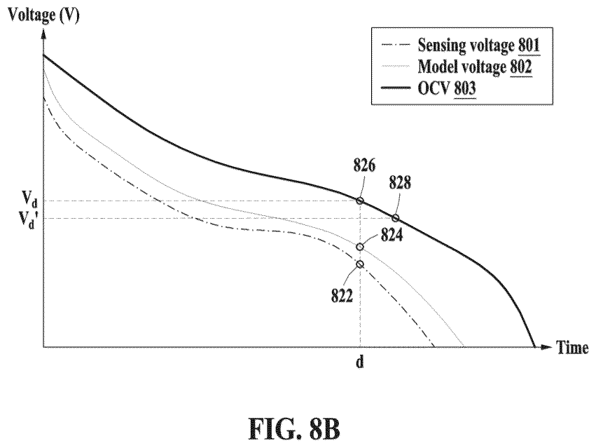

FIG. 8A illustrates an example of a method of determining a first OCV to determine an electrode balance shift.

The x-axis of the graph shown may correspond to the time during which the battery is being discharged or the amount of decrease in the SOC.

According to an example, at a time point c, the first value of the model parameter may correspond to a third threshold value set for the model parameter. For example, a value of the anode ion concentration determined based on the sensing data may correspond to the third threshold value (e.g., 0.3) at the time point c. The time point c may be in the interval 420 described above with reference to FIG. 4.

When the condition for the value of the cathode ion concentration is satisfied in addition to the condition for the value of the anode ion concentration, the time point c may be determined. For example, additional conditions may be satisfied when the value of the cathode ion concentration is greater than or equal to a specific threshold value (e.g., 0.75).

A third model voltage 814 of the battery may be determined using the battery model. A third model OCV 816 of the battery may be determined using the battery model. The model overpotential may be determined by a value obtained by subtracting the third model voltage 814 from the third model OCV 816. A third OCV 818 may be determined as the sum of the model overpotential and a third sensing voltage 812.

According to an example, a third SOC corresponding to the third OCV 818 may be determined. For example, the third SOC corresponding to the third OCV may be determined based on the predefined LUT for the relationship between an OCV curve 803 and an SOC of the battery.

FIG. 8B illustrates an example of a method of determining a second OCV to determine an electrode balance shift.

The x-axis of the graph shown may correspond to the time during which the battery is being discharged or the amount of decrease in the SOC.

According to an example, at a time point d, a fourth value of the model parameter may correspond to a fourth threshold value set for the model parameter. For example, a value of the anode ion concentration determined based on the sensing data may correspond to the fourth threshold value (e.g., 0.1) at the time point d. The time point d may be in the interval 420 described above with reference to FIG. 4.

According to an example, a time point, at which the current SOC decreases by, for example, 10% or more, may be determined as the time point d compared to the third SOC determined with reference to FIG. 8.

A fourth model voltage 824 of the battery may be determined using the battery model. A fourth model OCV 826 of the battery may be determined using the battery model. The model overpotential may be determined by a value obtained by subtracting the fourth model voltage 824 from the fourth model OCV 826. A fourth OCV 828 may be determined as the sum of the model overpotential and a fourth sensing voltage 822.

According to an example, a fourth SOC corresponding to the fourth OCV 828 may be determined. For example, the fourth SOC corresponding to the fourth OCV may be determined based on the predefined LUT for the relationship between the OCV curve 803 and the SOC of the battery.

According to an example, the electrode balance shift may be determined as the value of the degradation parameter based on the cumulative current value consumed in the battery during the interval between the time point c and the time point d (or between the third SOC and the fourth SOC).

FIG. 9 illustrates an example of a method of determining a second OCV of a battery.

According to an example, operations 910 to 950 of FIG. 9 may be related to operation 535 described above with reference to FIG. 5. For example, operation 535 may include operations 910 to 950.

Operations 910 to 950 may be performed by an electronic device (e.g., the battery state estimation apparatus 120 of FIG. 1 or the electronic device 200 of FIG. 2). For example, the electronic device may include at least one processor (e.g., the processor 220 of FIG. 2) and a memory (e.g., the memory 230 of FIG. 2). Operations 910 to 950 of FIG. 9 may be performed in the sequence and manner as illustrated in FIG. 9. However, one or more of the operations may be performed in a different order, one or more of the operations may be omitted, two or more of the operations may be performed in parallel or simultaneously, and/or other operations may be additionally performed without departing from the spirit and scope of the described embodiments.

In operation 910, the electronic device may obtain second sensing data measured from one or more sensors connected to a battery. For example, the second sensing data may include voltage data, current data, and/or temperature data.

In operation 920, the electronic device may determine a second value of a model parameter of a battery model configured to estimate a state of the battery based on the second sensing data. The description of the method of determining the second value of the model parameter may be replaced with the description of operation 510 of determining the first value of the model parameter.

In operation 930, the electronic device may determine whether the second value of the model parameter corresponds to a second threshold value set for the model parameter. For example, the model parameter may be the anode ion concentration.

The second threshold value may correspond to an end point of the interval 410 described above with reference to FIG. 4. For example, when the model parameter is the anode ion concentration and the degradation parameter is a ratio of change in the capacity for the cathode active material, the second threshold value set for the model parameter may be a value between 0.65 and 0.40.

The second threshold value may correspond to an end point of the interval 420 described above with reference to FIG. 4. For example, when the model parameter is the anode ion concentration and the degradation parameter is an electrode balance shift, the second threshold value set for the model parameter may be a value between 0.20 and 0.05.

When the second value of the model parameter does not correspond to the second threshold value set for the model parameter, operations 910 to 930 may be performed repeatedly (e.g., repeatedly or iteratively performed until the second value of the model parameter corresponds to the second threshold value set for the model parameter).

In operation 940, when the second value of the model parameter corresponds to the second threshold value set for the model parameter, the electronic device may determine a second model overpotential of the battery using the battery model.

In operation 950, the electronic device may determine a second OCV of the battery based on a second sensing voltage of the battery among the second sensing data and the second model overpotential. For example, the sum of the second sensing voltage and the second model overpotential of the battery may be determined as the second OCV.

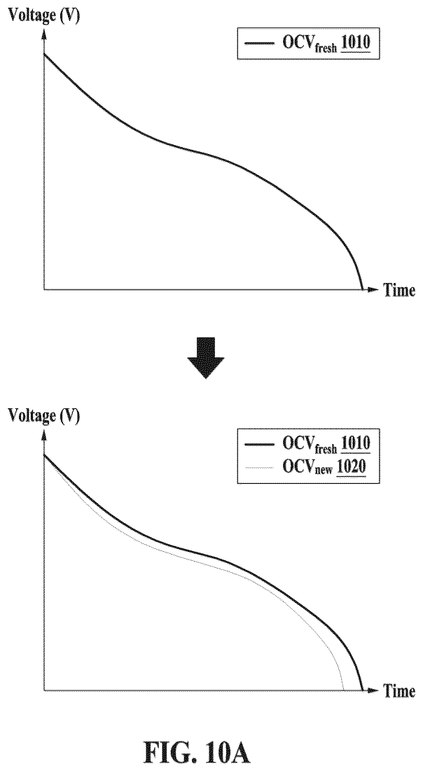

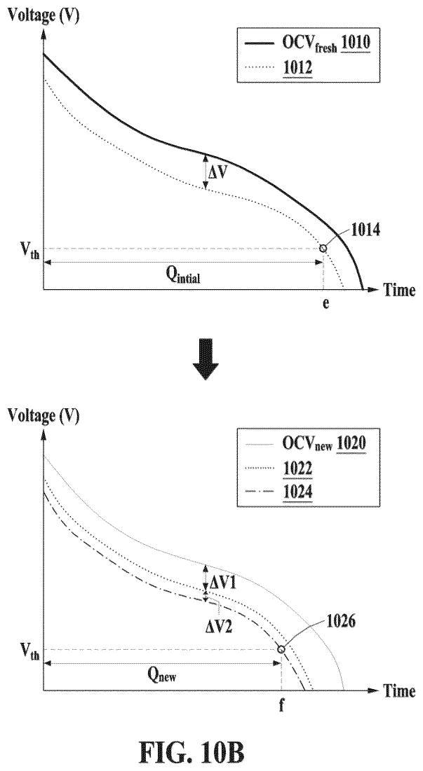

FIG. 10A illustrates a fresh OCV curve shown in a state where a battery is fresh and an adjusted OCV curve determined based on SOCs determined during usage of the battery.

The x-axis of the graph shown may correspond to the time during which the battery is being discharged or the amount of decrease in the SOC.

According to an example, the OCV curve of the battery may be adjusted as the value of the degradation parameter is updated. For example, an OCV_{fresh} curve 1010 of the battery in a fresh state may be changed to an OCV_{new} curve 1020 of the battery in a degraded state. Compared to the OCV_{fresh} curve 1010 of the battery in the fresh state, the OCV_{new} curve 1020 of the battery in the degraded state may have a lower voltage at the same discharge time point. Overall, as the OCV voltage decreases, the SOH of the battery may decrease.

FIG. 10B illustrates an example of initial battery capacity determined based on a fresh OCV curve and current battery capacity determined based on an adjusted OCV curve.

According to an example, a standard discharge overpotential curve 1012 may be determined for the OCV_{fresh} curve 1010 of the battery in the fresh state. For example, the standard discharge overpotential curve 1012 may have a difference ΔV from the OCV_{fresh} curve 1010 by the voltage drop caused by initial resistance of the cell. The voltage dropped by the initial resistance may be determined as the product of the current and the initial resistance.

Initial battery capacity Qᵢₙᵢₜᵢₐₗ may be the cumulative discharged charge amount from a discharge start time point until a time point e until the standard discharge overpotential curve 1012 reaches a preset threshold voltage Vₜₕ. For example, the threshold voltage Vₜₕ may be 3.3 V and is not limited to the described example.

According to an example, a first standard discharge overpotential curve 1022 may be determined for the OCV_{new} curve 1020 of the battery in the degraded state. For example, the first standard discharge overpotential curve 1022 may have a difference ΔV1 from the OCV_{new} curve 1020 by the voltage drop caused by initial resistance of the cell. The voltage dropped by the initial resistance may be determined as the product of the current and the initial resistance.

A second standard overpotential curve 1024 may be determined based on the first standard discharge overpotential curve 1022. For example, the second standard discharge overpotential curve 1024 may have a difference ΔV2 from the first standard discharge overpotential curve 1022 by the voltage drop caused by SEI resistance. The SEI resistance may be determined based on the battery model. As the value of the degradation parameter is updated, the SEI resistance determined based on the battery model may increase.

Current battery capacity Q_{new} may be the cumulative discharged charge amount from a discharge start time point until a time point f until the second standard discharge overpotential curve 1024 reaches a preset threshold voltage Vₜₕ.

According to an example, the SOH as the state information of the battery may be determined based on the initial battery capacity Qᵢₙᵢₜᵢₐₗ and the current battery capacity Q_{new}. For example, the SOH may be determined by Equation 4 described above.

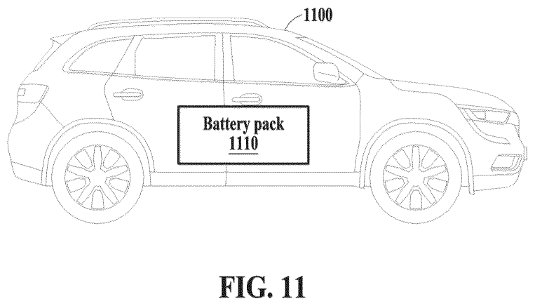

FIG. 11 illustrates an example of a vehicle.

Referring to FIG. 11, a vehicle 1100 includes a battery pack 1110. The vehicle 1100 may be a vehicle using the battery pack 1110 as a power source. The vehicle 1100 may be, for example, an electric vehicle or a hybrid vehicle.

The battery pack 1110 includes a battery management system (BMS) and battery cells (or battery modules). The BMS may monitor whether the battery pack 1110 shows an abnormality, and prevent over-charging or over-discharging of the battery pack 1110. Further, the BMS may perform thermal control for the battery pack 1110 when the temperature of the battery pack 1110 exceeds a first temperature (e.g., 40° C.) or is lower than a second temperature (e.g., −10° C.). In addition, the BMS may perform cell balancing so that the battery cells in the battery pack 1110 have balanced charging states.

According to an example, the vehicle 1100 includes a battery state estimation apparatus (e.g., the battery state estimation apparatus 120 of FIG. 1 or the electronic device 200 of FIG. 2). The battery state estimation apparatus may determine the state information of the battery pack 1110 (or the battery cells in the battery pack 1110).

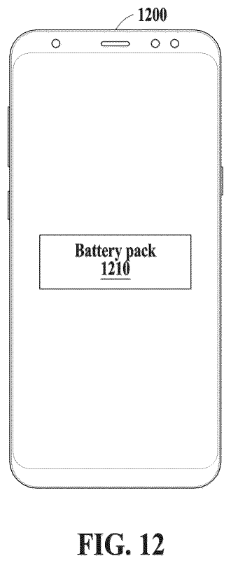

FIG. 12 illustrates an example of a mobile terminal.

Referring to FIG. 12, a mobile terminal 1200 includes a battery pack 1210. The mobile terminal 1200 may be a device that uses the battery pack 1210 as a power source. The mobile terminal 1200 may be a portable terminal, for example, a smartphone. The battery pack 1210 includes a BMS and battery cells (or battery modules).

According to an example, the mobile terminal 1200 includes a battery state estimation apparatus (e.g., the battery state estimation apparatus 120 of FIG. 1 or the electronic device 200 of FIG. 2). The battery state estimation apparatus may determine the state information of the battery pack 1210 (or the battery cells in the battery pack 1210).

According to an example, the mobile terminal 1200 may include a display, a battery that supplies power to the display, at least one processor including processing circuitry, and a memory including one or more storage media that store instructions. For example, operations 505 to 555 described above with reference to FIG. 5 may be performed by the mobile terminal 1200 by the instructions.

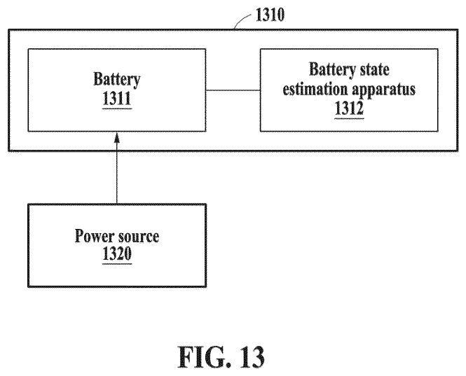

FIG. 13 illustrates an example of an electronic device.

Referring to FIG. 13, an electronic device 1310 (e.g., the electronic device 200 of FIG. 2) may include a battery 1311 and a battery state estimation apparatus 1312. The electronic device 1310 may be a mobile terminal, such as a smartphone, a laptop, a tablet PC, and/or a wearable device, but is not limited thereto. The battery 1311 may be charged by receiving power from a power source 1320. The battery state estimation apparatus 1312 may determine state information of the battery 1311.

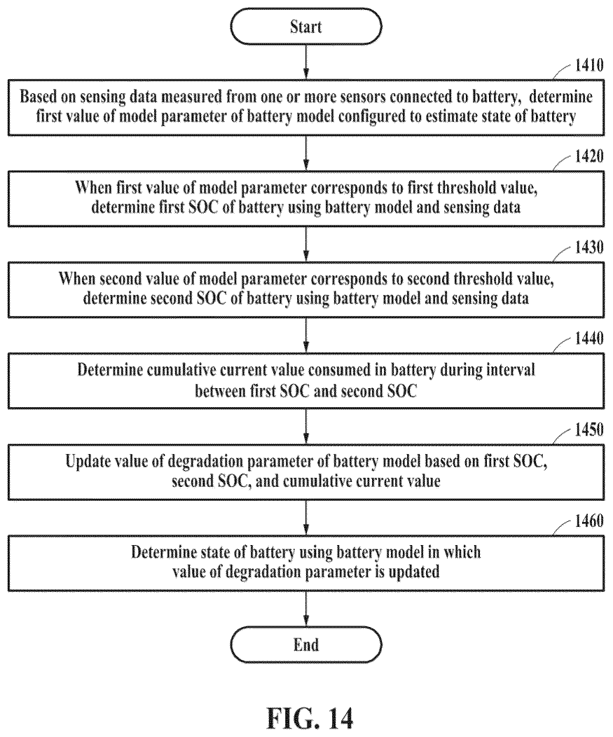

FIG. 14 illustrates an example of a method of determining a battery state.

Operations 1410 to 1460 of FIG. 14 may be performed by an electronic device (e.g., the battery state estimation apparatus 120 of FIG. 1 or the electronic device 200 of FIG. 2). For example, the electronic device may include at least one processor (e.g., the processor 220 of FIG. 2) and a memory (e.g., the memory 230 of FIG. 2). Operations 1410 to 1460 of FIG. 14 may be performed in the sequence and manner as illustrated in FIG. 14. However, one or more of the operations may be performed in a different order, one or more of the operations may be omitted, two or more of the operations may be performed in parallel or simultaneously, and/or other operations may be additionally performed without departing from the spirit and scope of the described embodiments.

In operation 1410, the electronic device may obtain sensing data measured from one or more sensors connected to a battery. The sensing data obtained in operation 1410 may be referred to as first sensing data to distinguish it from other sensing data. The description of operation 1410 may be replaced with the description of operation 505 described above with reference to FIG. 5.

In operation 1420, the electronic device may determine a first SOC of the battery using a battery model and sensing data when a first value of a model parameter corresponds to a first threshold value. For example, the electronic device may determine the first value of the model parameter of the battery model that estimates the state of the battery based on the first sensing data, and determine whether the determined first value corresponds to the first threshold value. The first threshold value may be a preset value for the model parameter. The description of operation 1420 may be replaced with the descriptions of operations 510 and 515 provided above with reference to FIG. 5. For example, operation 1420 may include operations 510 and 515.

According to an example, operation 1420 may include operations 610 to 630 described above with reference to FIG. 6. For example, the electronic device may determine a first OCV of the battery based on a first sensing voltage of the battery among the first sensing data and a first model overpotential, and determine the first SOC corresponding to the first OCV.

In operation 1430, the electronic device may determine a second SOC of the battery using the battery model and the sensing data when a second value of the model parameter corresponds to a second threshold value. The sensing data described in operation 1430 may be referred to as second sensing data to distinguish it from other sensing data. For example, the electronic device may determine the second value of the model parameter of the battery model that estimates the state of the battery based on the second sensing data, and determine whether the determined second value corresponds to the second threshold value. The second threshold value may be a preset value for the model parameter. The description of operation 1430 may be replaced with the descriptions of operations 535 and 540 provided above with reference to FIG. 5. For example, operation 1430 may include operations 535 and 540.

According to an example, operation 1430 may include operations 610 to 630 described above with reference to FIG. 6. For example, the electronic device may determine a second OCV of the battery based on a second sensing voltage of the battery among the second sensing data and a second model overpotential, and determine the second SOC corresponding to the second OCV.

In operation 1440, the electronic device may determine a cumulative current value consumed in the battery during the interval between the first SOC and the second SOC. The description of operation 1440 may be replaced with the description of operation 545 described above with reference to FIG. 5.

In operation 1450, the electronic device may update the value of the degradation parameter of the battery model based on the first SOC, the second SOC, and the cumulative current value. The description of operation 1450 may be replaced with the description of operation 550 described above with reference to FIG. 5.

In operation 1460, the electronic device may determine the state of the battery using the battery model in which the value of the degradation parameter is updated. The description of operation 1460 may be replaced with the description of operation 555 described above with reference to FIG. 5.

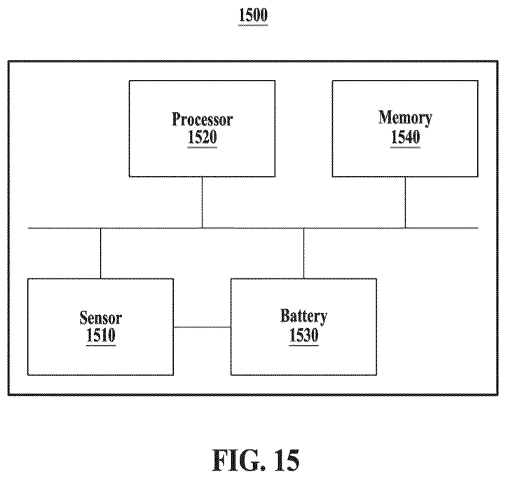

FIG. 15 illustrates an example of an electronic device.

Referring to FIG. 15, an electronic device 1500 may include a sensor 1510 (e.g., one or more sensors), a processor 1520 (e.g., one or more processors), a battery 1530 (e.g., one or more batteries), and a memory 1540 (e.g., one or memories). The electronic device 1500 may be or include any one, any combination or all of the battery system 100, the battery state estimation apparatus 120, the electronic device 200, the vehicle 1100, the mobile terminal 1200, the electronic device 1310, and the battery state estimation apparatus 1312 described herein. The sensor 1510 may be or include any one, any combination or all of the sensors described herein. The processor 1520 may be or include the processor 220 described herein. The battery 1530 may be or include any one, any combination or all of the battery 110, the battery pack 1110, the battery pack 1210, the battery 1311, and the power source 1320 described herein. The memory 1540 may be or include the memory 230 described herein.

The sensor 1510 may sense or measure sensing data including voltage data, current data, and/or temperature data from the battery 1530. The sensor 1510 may be or include a voltage sensor, a current sensor, and/or a temperature sensor.

The battery systems, batteries, battery state estimation apparatuses, electronic devices, communicators, processors, memories, vehicles, battery packs, mobile terminals, power sources, sensors, battery system 100, battery 110, battery state estimation apparatus 120, electronic device 200, communicator 210, processor 220, memory 230, vehicle 1100, battery pack 1110, mobile terminal 1200, battery pack 1210, electronic device 1310, battery 1311, battery state estimation apparatus 1312, power source 1320, electronic device 1500, sensor 1510, processor 1520, battery 1530, and memory 1540 described herein, including descriptions with respect to respect to FIGS. 1-14, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1-14 that perform the operations described in this application are performed by computing hardware, for example, by one or more processors or computers, implemented as described above implementing instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method comprising:
based on first sensing data measured from one or more sensors connected to a battery of an electronic device, determining a first value of a model parameter of a battery model configured to estimate a state of the battery;
in response to the first value of the model parameter corresponding to a first threshold value, determining a first state of charge (SOC) of the battery using the battery model and the first sensing data;
in response to a second value of the model parameter corresponding to a second threshold value set for the model parameter, determining a second SOC;
determining a cumulative current value consumed in the battery during an interval between the first SOC and the second SOC;
updating a value of a degradation parameter of the battery model based on the first SOC, the second SOC, and the cumulative current value; and
determining the state of the battery using the battery model in which the value of the degradation parameter is updated.

2. The method of claim 1, further comprising:
determining a first model voltage of the battery using the battery model;
determining a first model open circuit voltage (OCV) of the battery using the battery model; and
determining a first model overpotential based on the first model voltage and the first model OCV,
wherein the determining of the first SOC comprises:
determining a first OCV of the battery based on a first sensing voltage of the battery among the first sensing data and the first model overpotential; and
determining the first SOC corresponding to the first OCV.

3. The method of claim 2, wherein the determining of the first SOC corresponding to the first OCV comprises determining the first SOC corresponding to the first OCV using a look up table (LUT) that shows a relationship between an OCV and an SOC of the battery.

4. The method of claim 1, wherein the determining of the second SOC comprises:
obtaining second sensing data measured from the one or more sensors connected to the battery;
determining a second value of the model parameter based on the second sensing data;
determining whether the second value of the model parameter corresponds to a second threshold value set for the model parameter;
in response to the second value of the model parameter corresponding to the second threshold value, determining a second model overpotential of the battery using the battery model;
determining a second OCV of the battery based on a second sensing voltage of the battery among the second sensing data and the second model overpotential; and
determining the second SOC corresponding to the second OCV.

5. The method of claim 1, wherein the state of the battery comprises a state of health (SOH) of the battery.

6. The method of claim 1, wherein the model parameter is an anode ion concentration.

7. The method of claim 6, wherein the first threshold value set for the model parameter, which is the anode ion concentration, is a value between 0.85 and 0.65.

8. The method of claim 7, wherein the second threshold value set for the model parameter, which is the anode ion concentration, is a value between 0.65 and 0.40.

9. The method of claim 7, wherein the degradation parameter is a change ratio of capacity of a cathode active material.

10. The method of claim 6, wherein the first threshold value set for the model parameter, which is the anode ion concentration, is a value between 0.40 and 0.20.

11. The method of claim 10, wherein the second threshold value set for the model parameter, which is the anode ion concentration, is a value between 0.20 and 0.05.

12. The method of claim 10, wherein the degradation parameter is an electrode balance shift.

13. The method of claim 1, wherein the electronic device is a mobile terminal.

14. A non-transitory computer-readable storage medium storing code that, when executed by one or more processors, configures the one or more processors to perform the method of claim 1.

15. An electronic device comprising:
one or more processors configured to:
based on first sensing data measured from one or more sensors connected to a battery of the electronic device, determine a first value of a model parameter of a battery model configured to estimate a state of the battery;
in response to the first value of the model parameter corresponding to a first threshold value, determine a first state of charge (SOC) of the battery using the battery model and the first sensing data;
in response to a second value of the model parameter corresponding to a second threshold value set for the model parameter, determine a second SOC;
determine a cumulative current value consumed in the battery during an interval between the first SOC and the second SOC;
update a value of a degradation parameter of the battery model based on the first SOC, the second SOC, and the cumulative current value; and
determine the state of the battery using the battery model in which the value of the degradation parameter is updated.

16. An electronic device comprising:
one or more processors configured to:
obtain first sensing data measured from one or more sensors connected to a battery;
determine a first value of a model parameter of a battery model configured to estimate a state of the battery based on the first sensing data;
determine whether the first value of the model parameter corresponds to a first threshold value set for the model parameter;
in response to the first value of the model parameter corresponding to the first threshold value, determine a first model overpotential of the battery using the battery model;
determine a first open circuit voltage (OCV) of the battery based on a first sensing voltage of the battery among the first sensing data and the first model overpotential;
determine a first state of charge (SOC) corresponding to the first OCV;
determine a second OCV of the battery based on a second model overpotential of the battery determined in response to a second value of the model parameter corresponding to a second threshold value set for the model parameter;
determine a second SOC corresponding to the second OCV;
determine a cumulative current value consumed in the battery during an interval between the first SOC and the second SOC;
update a value of a degradation parameter of the battery model based on the first SOC, the second SOC, and the cumulative current value; and
determine the state of the battery using the battery model in which the value of the degradation parameter is updated.

17. The mobile terminal of claim 16, wherein the one or more processors are configured to:
determine a first model voltage of the battery using the battery model;
determine a first model OCV of the battery using the battery model; and
for determining of the first model overpotential, determine the first model overpotential based on the first model voltage and the first model OCV.

18. The mobile terminal of claim 16, wherein the one or more processors are configured to:
obtain second sensing data measured from the one or more sensors connected to the battery;
determine the second value of the model parameter based on the second sensing data;
determine whether the second value of the model parameter corresponds to the second threshold value set for the model parameter;
in response to the second value of the model parameter corresponding to the second threshold value, determine a second model overpotential of the battery using the battery model; and
for the determining of the second OCV of the battery, determine the second OCV of the battery based on a second sensing voltage of the battery among the second sensing data and the second model overpotential.

19. The mobile terminal of claim 16, wherein the model parameter is an anode ion concentration.

20. The mobile terminal of claim 16, wherein the degradation parameter is a change ratio of capacity of a cathode active material or an electrode balance shift.
